(19) United States
(12) Patent Application Publication
(10) Pub. No.: US 2017/0366193 A1
(43) Pub. Date: Dec. 21, 2017

(54) PROGRAMMABLE FREQUENCY DIVIDER, PLL SYNTHESIZER AND RADAR DEVICE

(71) Applicant: FUJITSU LIMITED, Kawasaki-shi (JP)

(72) Inventor: Hiroshi Matsumura, Isehara (JP)

(73) Assignee: FUJITSU LIMITED, Kawasaki-shi (JP)

(21) Appl. No.: 15/609,925

(22) Filed: May 31, 2017

(30) Foreign Application Priority Data
Jun. 21, 2016 (JP) 2016-122828

(51) Int. Cl. H03L 7/199; H03K 23/66; G01S 7/02

(52) U.S. Cl. CPC H03L 7/199; G01S 7/02; H03K 23/667

(57) ABSTRACT

A programmable frequency divider includes a modulus frequency divider, a pulse counter, and a swallow counter. The pulse counter is configured to count an output signal from the modulus frequency divider, and output a frequency division signal, and the swallow counter is configured to count the output signal from the modulus frequency divider and perform resetting on the basis of the frequency division signal from the pulse counter, the programmable frequency divider being configured to control the modulus frequency divider on the basis of a signal from the swallow counter. The programmable frequency divider includes a control signal delay circuit, disposed between an output terminal of the swallow counter and a control terminal of the modulus frequency divider, configured to delay a signal from the swallow counter, and generate a control signal for controlling the modulus frequency divider.

### CROSS-REFERENCE TO RELATED APPLICATION

This application is based upon and claims the benefit of priority of the prior Japanese Patent Application No. 2016-122828, filed on Jun. 21, 2016, the entire contents of which are incorporated herein by reference.

### FIELD

The embodiments discussed herein are related to a programmable frequency divider, a PLL synthesizer and a radar device.

### BACKGROUND

Conventionally, a programmable frequency divider is adopted in a PLL (Phase Locked Loop) circuit (PLL synthesizer) of a radar device or radio communication equipment that handles a millimeter-wave signal, and is used as a signal source of a millimeter-wave signal. In order to generate an accurate millimeter-wave signal, such a programmable frequency divider requires robust operation regardless of a change of temperature environments where a radar device or the like is used (temperature fluctuation), a change of power supply voltage (voltage fluctuation), process variations of a semiconductor, or the like.

In other words, when the operation of the programmable frequency divider fluctuates due to temperature fluctuation, voltage fluctuation, process variations, or the like, for example, the function itself of a radio system can be lost as erroneous operation of the signal source occurs. Therefore, the programmable frequency divider requires stable operation irrespective of temperature fluctuation, voltage fluctuation, process variations, or the like.

As described above, as a pulse swallow-type programmable frequency divider including a dual modulus frequency divider, a pulse counter and a swallow counter, there has been proposed various ones. However, for example, timing of normally picking up logic can be deviated from the design because propagation delay times of the pulse counter and the swallow counter vary with temperature fluctuation, voltage fluctuation, process variations, or the like.

In particular, when a pulse swallow-type programmable frequency divider is operated at high speed, delay variations of the pulse counter and the swallow counter become relatively larger. Therefore, for example, the pulse swallow-type programmable frequency divider is used at a reduced operation speed or adopts a complicated circuit configuration in order to allow a sufficient margin for the variations.

In other words, for example, as the programmable frequency divider used for generating a millimeter-wave signal, those capable of stable operation irrespective of temperature fluctuation, voltage fluctuation, process variations, or the like without adopting a complicated circuit configuration have not been put into practical use under present circumstances.

Incidentally, in the past, for example, as a dual modulus frequency divider, and a pulse swallow-type programmable frequency divider including a pulse counter and a swallow counter, there has been proposed various ones.

Patent Document 1: Japanese National Publication of International Patent Application No. 2003-515963

Patent Document 2: Japanese Patent No. S60(1988)-041892

### SUMMARY

According to an aspect of the embodiments, there is provided a programmable frequency divider includes a modulus frequency divider, a pulse counter, and a swallow counter. The pulse counter is configured to count an output signal from the modulus frequency divider, and output a frequency division signal, and the swallow counter is configured to count the output signal from the modulus frequency divider and perform resetting on the basis of the frequency division signal from the pulse counter, the programmable frequency divider being configured to control the modulus frequency divider on the basis of a signal from the swallow counter.

The programmable frequency divider includes a control signal delay circuit, disposed between an output terminal of the swallow counter and a control terminal of the modulus frequency divider, configured to delay a signal from the swallow counter, and generate a control signal for controlling the modulus frequency divider.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating an example of a PLL synthesizer;

FIG. 2 is a block diagram illustrating an example of a programmable frequency divider;

FIG. 3A and FIG. 3B are explanatory diagrams of an example of operation of a dual modulus frequency divider of the programmable frequency divider illustrated in FIG. 2;

FIG. 4A and FIG. 4B are explanatory diagrams of an example of erroneous operation of the dual modulus frequency divider illustrated in FIG. 3A and FIG. 3B;

FIG. 5A and FIG. 5B are explanatory diagrams of an example of operation of a swallow counter of the programmable frequency divider illustrated in FIG. 2;

FIG. 6 is an explanatory diagram of an example of erroneous operation of the swallow counter illustrated in FIG. 5A and FIG. 5B;

FIG. 7 is a block diagram illustrating an example of a programmable frequency divider according to the present example;

FIG. 8 is an explanatory diagram of an example of operation of the programmable frequency divider illustrated in FIG. 7;

FIG. 9 is an explanatory diagram of an effect of the programmable frequency divider illustrated in FIG. 7;

FIG. 10 is an explanatory flowchart of an example of compensation operation of the programmable frequency divider according to the present example;

FIG. 11 is a circuit diagram illustrating an example of a control signal delay circuit and a reset signal delay circuit of the programmable frequency divider illustrated in FIG. 7;

FIG. 12 is a circuit diagram illustrating an example of a pulse width variable swallow counter of the programmable frequency divider illustrated in FIG. 7; and

FIG. 13 is a block diagram illustrating an example of a radar device adopting the programmable frequency divider according to the present example.

### DESCRIPTION OF EMBODIMENTS

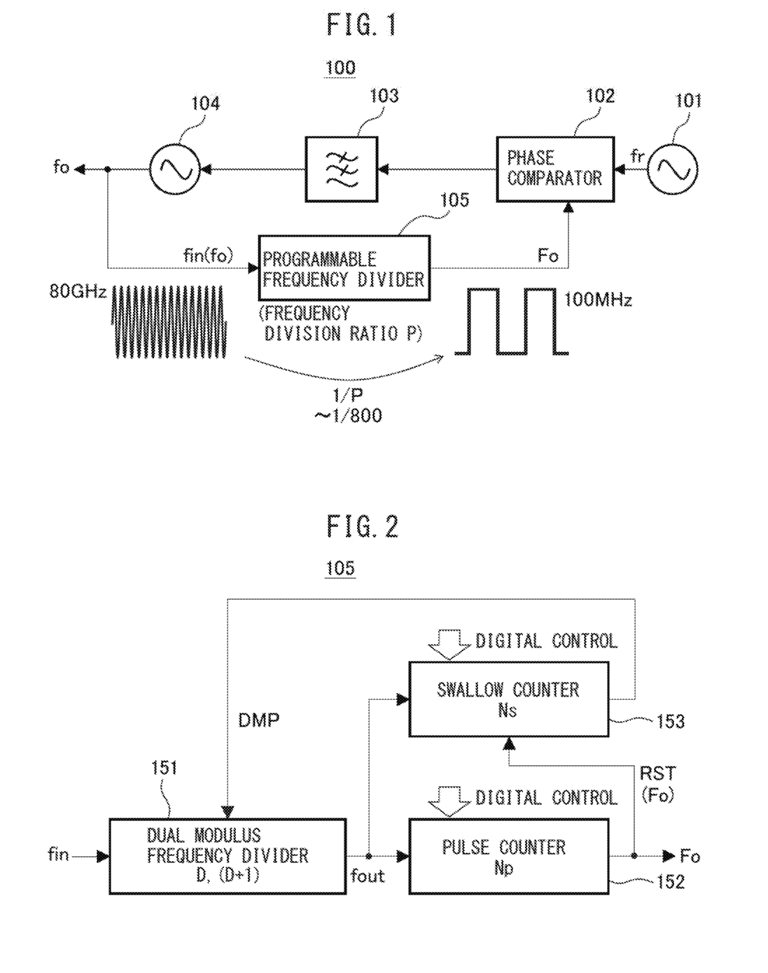

First, before a programmable frequency divider, a PLL synthesizer and a radar device according to the present example are described in detail, an example of a PLL synthesizer and a programmable frequency divider as well as challenges of the programmable frequency divider is described with reference to FIG. 1 to FIG. 6.

FIG. 1 is a block diagram illustrating an example of a PLL synthesizer. As illustrated in FIG. 1, a PLL synthesizer 100 includes, for example, a crystal oscillator (signal source) 101, a phase comparator 102, a low-pass filter (LPF) 103, a voltage-controlled oscillator (VCO: Voltage-controlled oscillator) 104, and a programmable frequency divider 105.

For example, the crystal oscillator 101 generates a reference signal fr having a frequency of 100 MHz. The phase comparator 102 receives the reference signal fr from the crystal oscillator 101 and an output (frequency division signal Fo) of the programmable frequency divider 105, and compares the phases. An output of the phase comparator 102 is input to the VCO 104 via the LPF 103.

In other words, the LPF 103 allows a low-frequency component of the output of the phase comparator 102 to pass therethrough and blocks a high-frequency component. For example, the VCO 104 generates a signal of 80 GHz and outputs it as an output signal fo on the basis of an output (voltage signal) of the LPF 103. The output signal fo from the VCO 104 is given as an input signal fin to the programmable frequency divider 105.

For example, the programmable frequency divider 105 controls a frequency division ratio P and changes an output frequency division number. Specifically, when the input signal fin (fo) of the programmable frequency divider 105 is 80 GHz and the crystal oscillator 101 generates a signal of 100 MHz, the frequency division ratio P is about 800. The frequency divider (programmable frequency divider 105) is a counter, which counts the number of pulses of the input signal fin and, for example, outputs a pulse (Fo) once every 800 times.

In other words, the output frequency fo of the oscillator (VCO) 104 of 80 GHz is a product (fo=P×fr) of the frequency division ratio P of the programmable frequency divider 105 and the frequency of the reference signal fr. Controlling the frequency division ratio P enables a change of the frequency of the output signal fo.

FIG. 2 is a block diagram illustrating an example of the programmable frequency divider, illustrating a pulse swallow-type programmable frequency divider which is widely used as a circuit system that realizes a high-speed programmable frequency divider. As illustrated in FIG. 2, a pulse swallow-type programmable frequency divider 105 includes a dual modulus frequency divider 151, a pulse counter 152, and a swallow counter 153. The pulse counter 152 and the swallow counter 153 are complicated digital control counters.

The dual modulus frequency divider 151 is capable of switching between two frequency division ratios: D and D+1, and its control signal (DMP) is received from the swallow counter 153. The pulse counter 152 and the swallow counter 153 use the output signal (fout) of the dual modulus frequency divider 151 as an input signal and count the number of pulses (Np, Ns). The numbers of counts Np and Ns are externally controlled.

The pulse counter 152 constantly repeats Np counting. Upon completion of counting, the pulse counter 152 outputs a High (high-level) pulse and then promptly starts next counting. In short, the pulse counter 152 operates as a 1/Np frequency division circuit.

The swallow counter 153 uses an output (frequency division signal Fo) from the pulse counter 152 as a reset signal (RST), and starts counting when a high-level pulse is input. In addition, the swallow counter 153 outputs High for the Ns counting after the start of counting, and the output falls to Low (low level) upon completion of counting. The swallow counter 153 is brought into a waiting state for resetting from the pulse counter 152.

In other words, as the state of the dual modulus frequency divider 151, the dual modulus frequency divider 151 is in a state of D+1 frequency division during Ns counting and is in a state of D frequency division during Np−Ns counting. According to the above operation, the entire frequency division ratio of the programmable frequency divider 105 can be represented as follows:

P=D×(Np−Ns)+(D+1)×Ns=D×Np+Ns

For example, with the pulse swallow-type programmable frequency divider 105 where D=4, Ns=0 to 3, and Np=16 to 31, when Ns and Np, which are externally given, are controlled to Ns=1 and Np=20, the pulse swallow-type programmable frequency divider 105 operates as a frequency divider where a frequency division ratio P=4×20 +1=81. In actual adoption, for example, when an input signal fin=10.1 GHz, D=4, Np=25, Ns=1, and a frequency division ratio P=101, frequency division signal Fo=100 MHz.

As described above, regarding the pulse swallow-type programmable frequency divider 105 illustrated in FIG. 2, the dual modulus frequency divider 151, which is a first stage, is a simple, two-mode switchable circuit that is capable of high-speed operation. In addition, the pulse counter 152 and the swallow counter 153, which are subsequent stages, are complicated circuits which are controlled in a programmable manner.

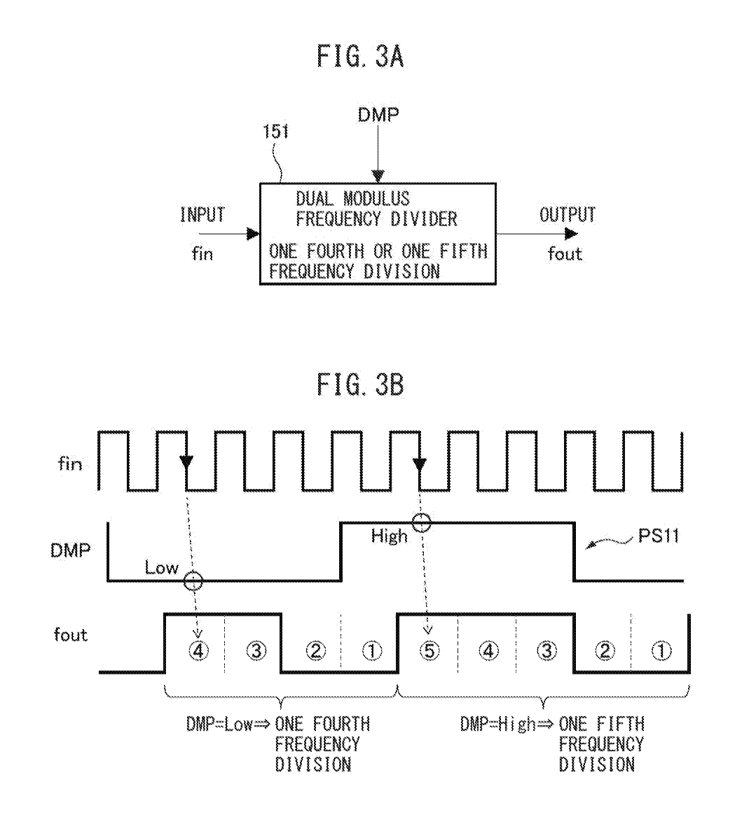

FIG. 3A and FIG. 3B are explanatory diagrams of an example of operation of a dual modulus frequency divider of the programmable frequency divider illustrated in FIG. 2. FIG. 3A illustrates the dual modulus frequency divider 151 that divides a frequency into one fourth or one fifth. FIG. 3B illustrates an explanatory timing chart of the operation.

As described above, the pulse counter 152 and the swallow counter 153 operate in cooperation. As illustrated in FIG. 3A, the dual modulus frequency divider 151 is controlled on the basis of the control signal DMP generated by the pulse counter 152 and the swallow counter 153, which operate in cooperation.

The dual modulus frequency divider 151 is limited in timing for picking up logic of the control signal DMP. In other words, as illustrated in FIG. 3B, the dual modulus frequency divider 151 is operated such that, when a pulse waveform PS11 of the DMP is High at the timing, a next output signal fout is one fifth frequency division and when the pulse waveform PS11 of the DMP is Low at the timing, a next output signal is one fourth frequency division. In this way, the dual modulus frequency divider 151 is adapted to determine whether to perform four counts or five counts on the basis of a logical value (Low or High) of the control signal DMP.

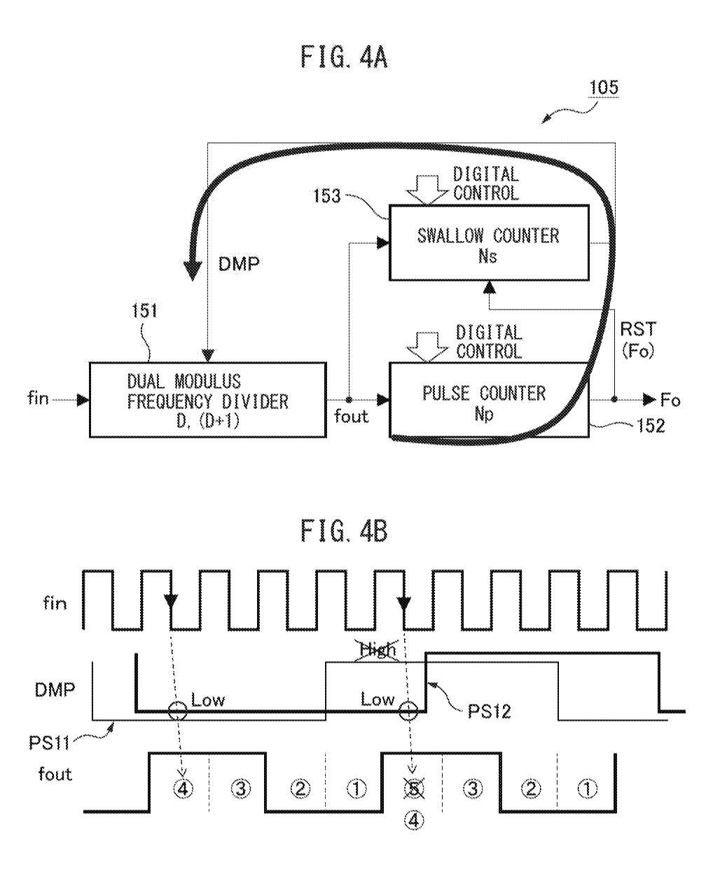

FIG. 4A and FIG. 4B are explanatory diagrams of an example of erroneous operation of the dual modulus frequency divider illustrated in FIG. 3A and FIG. 3B. FIG. 4A illustrates circuit delay of the programmable frequency divider 105, and FIG. 4B illustrates an explanatory timing chart of erroneous operation of the dual modulus frequency divider 151.

The pulse counter 152 and the swallow counter 153, which are subsequent stages, are, for example, large in circuit scale and configured as complicated circuits, so that operation delay is large. In other words, as illustrated in FIG. 4A, the time from when the dual modulus frequency divider 151 outputs the output signal fout and until when the dual modulus frequency divider 151 receives the control signal DMP is affected by operation delay of the pulse counter 152 and the swallow counter 153.

In addition, the operation delay of the pulse counter 152 and the swallow counter 153 largely vary, for example, with temperature fluctuation and voltage fluctuation, process variations or the like. In other words, the pulse counter 152 and the swallow counter 153 involve large absolute delay, and therefore variations in operation delay are also large.

Specifically, as illustrated in FIG. 4B, for example, the dual modulus frequency divider 151 changes the output signal fout for counting the input signal fin by performing four counts (D) or five counts (D+1) according to the logical value (Low or High) of the control signal DMP. At this time, when the pulse waveform PS11 of the control signal DMP is changed (delayed) to a pulse waveform PS12 due to variations in operation delay of the pulse counter 152 and the swallow counter 153, one fifth frequency division, which is to be performed normally, is changed to one fourth frequency division, resulting in erroneous operation of the dual modulus frequency divider 151.

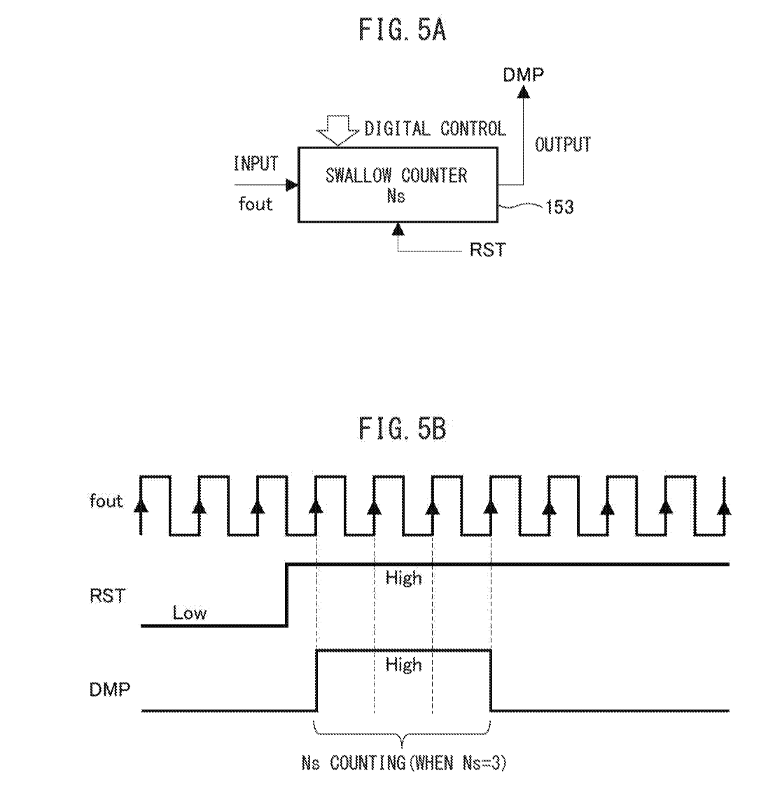

FIG. 5A and FIG. 5B are explanatory diagrams of an example of operation of the swallow counter of the programmable frequency divider illustrated in FIG. 2. FIG. 5A illustrates the swallow counter 153, and FIG. 5B illustrates an explanatory timing chart of the operation.

As illustrated in FIG. 5A, the swallow counter 153 counts the output signal fout (input signal to the swallow counter 153) of the dual modulus frequency divider 151, and gives a High output signal (control signal DMP) while counting and gives Low upon completion of counting. In addition, the swallow counter 153 starts counting at the first rising edge of fout after the reset signal RST from the pulse counter 152 becomes High. For the number of counts Ns, for example, a digital value is input from an external digital control circuit (digital control), and FIG. 5B illustrates the case where Ns=3.

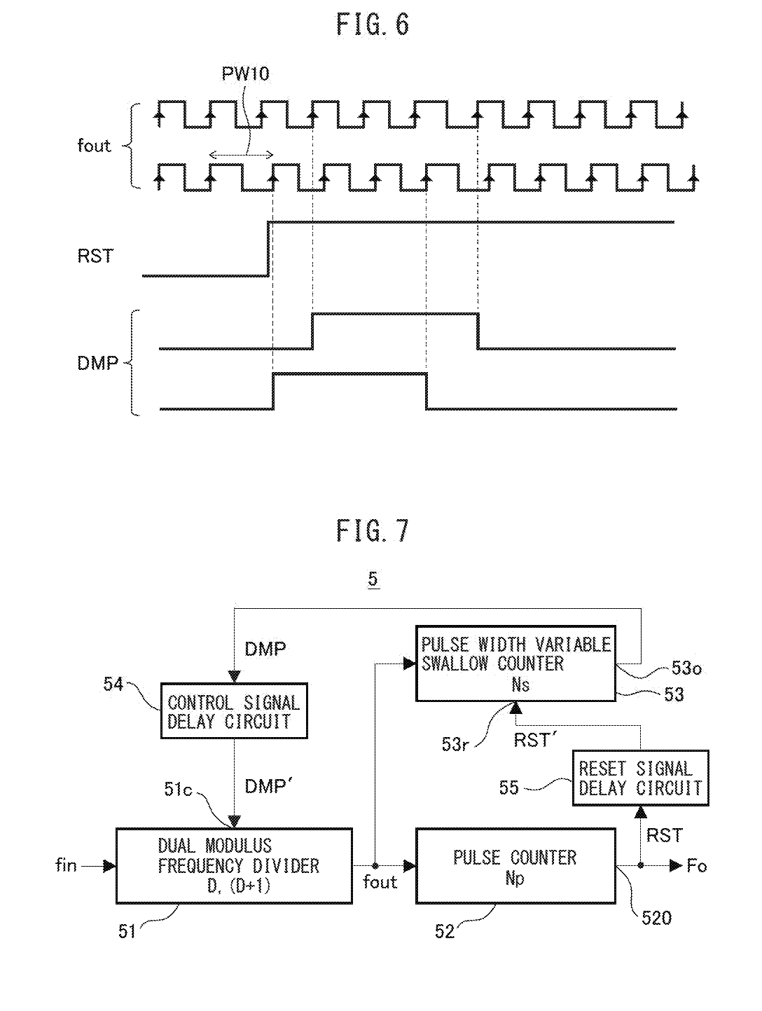

FIG. 6 is an explanatory diagram of an example of erroneous operation of the swallow counter illustrated in FIG. 5A and FIG. 5B. First, the input signal to the swallow counter 153 is the output signal fout of the dual modulus frequency divider 151, and therefore the period (pulse width) varies. Specifically, when the pulse width PW10 of the signal fout is longer, for example, the timing of fetching the reset signal RST varies even with respect to the same reset signal RST depending on the frequency division state of the dual modulus frequency divider 151, which is the preceding stage. Therefore, the output signal (control signal DMP) of the swallow counter 153 varies.

As described above, regarding the programmable frequency divider 105 illustrated in FIG. 2, for example, because the pulse counter 152 and the swallow counter 153 are large-scale circuits, erroneous operation can occur as the generation of the control signal DMP is delayed. In addition, it is difficult to make the programmable frequency divider 105 carry out normal operation irrespective of various fluctuations and variations since the operation delay varies with temperature fluctuation and voltage fluctuation, or process variations or the like. In addition, because pursuing high speed operation results in a shorter signal period, a permissible range enabling normal operation is increasingly narrowed.

In the following, an example of a programmable frequency divider, a PLL synthesizer and a radar device is described in detail with reference to the accompanying drawings. FIG. 7 is a block diagram illustrating an example of the programmable frequency divider according to the present example, illustrating a pulse swallow-type programmable frequency divider.

As illustrated in FIG. 7, a pulse swallow-type programmable frequency divider 5 includes a dual modulus frequency divider 51, a pulse counter 52, a pulse width variable swallow counter 53, a control signal delay circuit 54, and a reset signal delay circuit 55. The dual modulus frequency divider 51 and the pulse counter 52 correspond respectively to the dual modulus frequency divider 151 and the pulse counter 152 of FIG. 2 described above.

The control signal delay circuit 54 receives and delays the control signal DMP output from the pulse width variable swallow counter (swallow counter) 53, and outputs the delayed control signal DMP′ to the dual modulus frequency divider 51. In addition, the reset signal delay circuit 55 receives and delays the signal RST (frequency division signal Fo) output from the pulse counter 52, and outputs the delayed reset signal RST′ to the swallow counter 53.

In other words, both the control signal delay circuit 54 and the reset signal delay circuit 55 serve to adjust the absolute delay amount of an input signal and compensate the operation of the dual modulus frequency divider 51. In addition, the reset signal delay circuit 55 also serves to compensate the operation of the swallow counter 53. In short, the reset signal delay circuit 55 has also an effect of preventing the chance of unstable operation of the swallow counter 53, which would otherwise occur when the pulse edge of the input signal fout of the swallow counter 53 matches the pulse edge of the signal (frequency division signal) RST output from the pulse counter 52. The input signal to the swallow counter 53 is the output signal fout of the dual modulus frequency divider 51.

In addition, the swallow counter (pulse width variable swallow counter) 53 enables normal operation by adjusting the pulse width (duty ratio) when, for example, only one of the logics High and Low is not picked up normally. The swallow counter 53 is described in detail below with reference to FIG. 9 and FIG. 12.

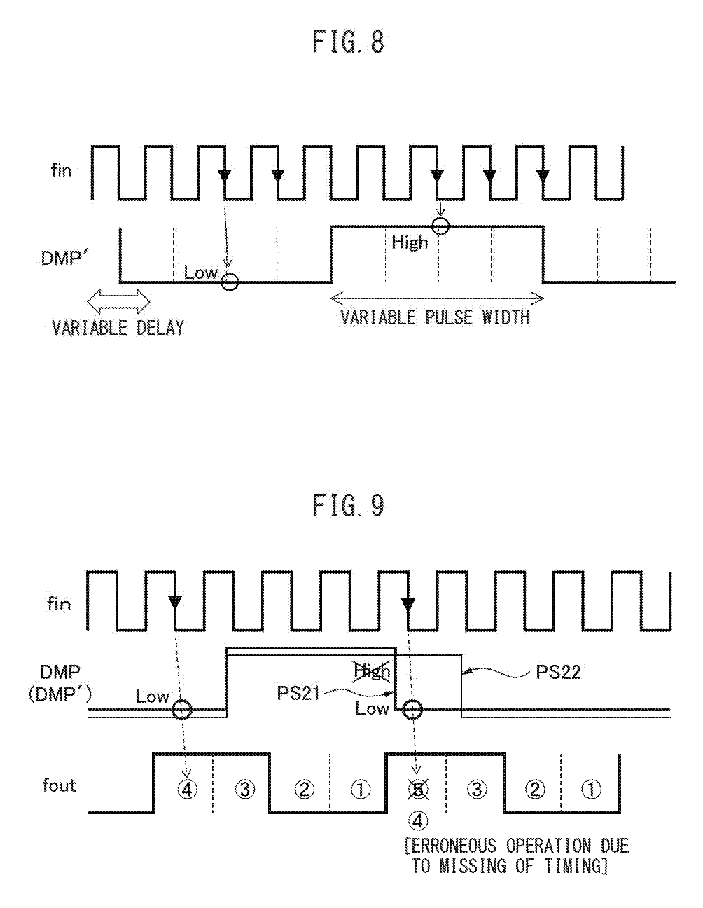

FIG. 8 is an explanatory diagram of an example of the operation of the programmable frequency divider illustrated in FIG. 7. As illustrated in FIG. 8, the control signal DMP′ given to the dual modulus frequency divider 51 involves an element of variable delay due to the control signal delay circuit 54 (reset signal delay circuit 55) and an element of pulse width variability due to the pulse width variable swallow counter 53.

First, as illustrated in FIG. 7, the control signal delay circuit 54 is provided between an output terminal 53o of the swallow counter 53 and a control terminal 51c of the dual modulus frequency divider 51, and gives variable delay to the output signal DMP of the swallow counter 53 to generate the control signal DMP′.

In other words, the control signal DMP′ for controlling the dual modulus frequency divider 51 is a signal obtained by giving variable delay due to the control signal delay circuit 54 to the signal DMP from the swallow counter 53. Thus, as illustrated in FIG. 8, the delay of the control signal DMP′ of the dual modulus frequency divider 51 is variably controlled.

In addition, the reset signal delay circuit 55 is provided between an output terminal 52o of the pulse counter 52 and a reset terminal 53r of the swallow counter 53, and performs controlling to give variable delay to the signal (frequency division signal) RST output from the pulse counter 52.

The swallow counter (pulse width variable swallow counter) 53 controls the pulse width (duty ratio) of the output signal DMP (control signal DMP′). Thus, as illustrated in FIG. 8, the pulse width of the signal DMP (DMP′) output from the swallow counter 53 is variably controlled. The variable controlling (adjustment of duty ratio) of the pulse width of the control signal DMP′ with the swallow counter 53 is effective when failure to capture data is likely to occur with respect to only one of the High logic and the Low logic.

FIG. 9 is an explanatory diagram of an effect of the programmable frequency divider illustrated in FIG. 7, describing the case where the aforementioned variable controlling of the pulse width is effective. In FIG. 9, a pulse waveform PS21 of the signal DMP′ (DMP) indicates the case where the variable controlling of the pulse width with the swallow counter 53 is not carried out. A pulse waveform PS22 indicates the case where the pulse width is variably controlled by the swallow counter 53 such that the period of the High logic is made longer.

As indicated by the pulse waveform PS21 of FIG. 9, for example, when the period of the High logic is short, the timing is missed and erroneous operation occurs such that a frequency, which is normally divided into one fifth, is divided into one fourth. In this case, the programmable frequency divider 5 of the present example adjusts the pulse width (duty ratio) such that the period of the High logic of the control signal DMP′ (DMP) is made longer. Thus, for example, failure to capture data of the High logic of the control signal DMP (DMP′) is eliminated, and erroneous operation can be prevented.

In the above, not both but only one of the control signal delay circuit 54 and the reset signal delay circuit 55 may be provided. In other words, the programmable frequency divider 5 of the present example may include only the control signal delay circuit 54, only the reset signal delay circuit 55, or both the control signal delay circuit 54 and the reset signal delay circuit 55.

As described above, when the delay amount of the control signal delay circuit and the delay amount of the reset signal delay circuit are set to optimum values, the programmable frequency divider capable of stable operation irrespective of temperature fluctuation, voltage fluctuation, process variations, or the like can be provided.

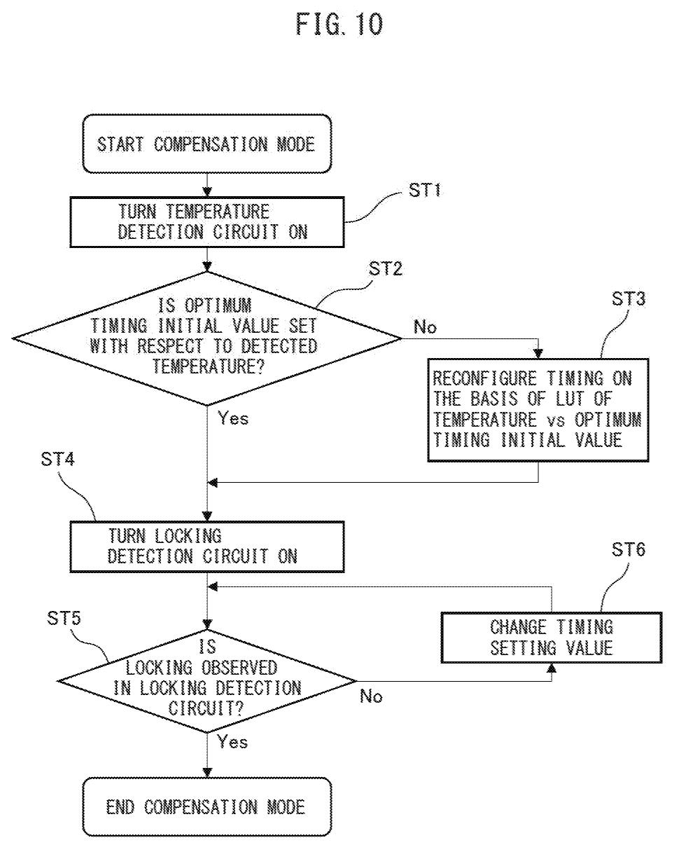

FIG. 10 is an explanatory flowchart of an example of compensation operation of the programmable frequency divider according to the present example. As illustrated in FIG. 10, when compensation operation (compensation mode) starts, a temperature detection circuit is turned ON in step ST1 and the compensation operation moves to step ST2 and determines whether optimum timing initial values are set with respect to the detected temperature. In other words, in step ST2, it is determined whether the delay amounts (setting values) of the control signal delay circuit 54 and the reset signal delay circuit 55 have been set to optimum timing initial values with respect to a temperature detected by the temperature detection circuit. Needless to say, the temperature detection circuit is provided in the vicinity of a device (e.g., a radar device) in which the programmable frequency divider is adopted.

When it is determined in step ST2 that optimum timing initial values are not set, the compensation operation moves to step ST3 and reconfigures the timing on the basis of a lookup table (LUT) of temperatures (detection temperatures) and optimum timing initial values, and moves to step ST4. In addition, when it is determined in step ST2 that optimum timing initial values have been set, the compensation operation moves to step ST4 directly.

In step ST4, a locking detection circuit is turned ON, and the compensation operation moves to step ST5 where the locking detection circuit determines whether locking is observed, i.e., whether the programmable frequency divider 5 performs predetermined operation. When it is determined in step ST5 that locking is not observed by the locking detection circuit, the compensation operation moves to step ST6, changes timing setting values, and returns to step ST5. Furthermore, when it is determined in step ST5 that locking is observed by the locking detection circuit, the compensation mode (compensation operation) is completed. FIG. 10 is for the sake of description of a mere example of the compensation mode of the programmable frequency divider, and of course, various changes and variations may be made.

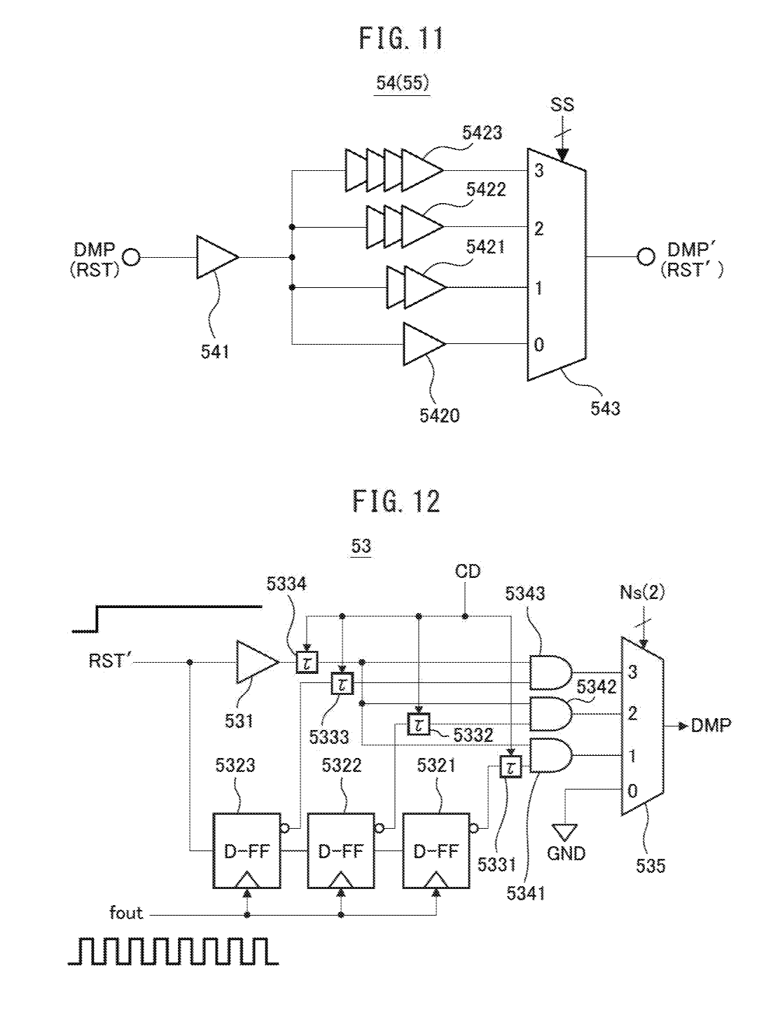

FIG. 11 is a circuit diagram illustrating an example of the control signal delay circuit and the reset signal delay circuit of the programmable frequency divider illustrated in FIG. 7, illustrating an example of a variable delay circuit. As illustrated in FIG. 11, the control signal delay circuit 54 (reset signal delay circuit 55) is adapted to include multiple buffers 541, 5420 to 5423, and a selector 543, and outputs the output signal DMP′ (RST′) obtained by giving different delay amounts to the input signal DMP (RST).

For example, the buffers 5420 to 5423 are adapted to be cascade-connected in different stages to form delay lines that give different delay amounts, so that any of outputs of the buffers (delay lines) 5420 to 5423 is selected by the selector 543 and output. In other words, in FIG. 11, the selector 543 selects any of the delay lines (outputs of the buffers 5420 to 5423) having four different delay amounts, for example, with a two-bit selection control signal SS. For example, the buffer 541 is to carry out shaping of the waveform of an input signal. In addition, FIG. 11 merely illustrates one example, and various changes and variations may be made.

FIG. 12 is a circuit diagram illustrating an example of a pulse width variable swallow counter of the programmable frequency divider illustrated in FIG. 7. As illustrated in FIG. 12, the pulse width variable swallow counter (swallow counter) 53 includes a buffer 531, flip-flops (D-FF) 5321 to 5323, variable delayers 5331 to 5334, AND gates (logic gates) 5341 to 5343, and a selector 535.

The swallow counter 53 illustrated in FIG. 12 sequentially fetches the reset signal RST′, for example, by using a signal fout as a fetching clock with the D-FFs, which are cascade-connected in three stages. Inverted outputs of the D-FFs 5323 to 5321 are connected to one of inputs of the AND gates 5343 to 5341 via the variable delayers 5333 to 5331, respectively. The reset signal RST′ is input to the other inputs of the AND gates 5343 to 5341 via the buffer 531 and the variable delayer 5334, which are connected in series. The delay amounts of the variable delayers 5331 to 5334 are controlled, for example, by a delay control data CD which is input from the outside.

Thus, as an input to the selector 535, signals with the different delay amounts due to the variable delayers 5331 to 5334 are input, and, for example, a signal selected by a two-bit selector control signal Ns(2) is output as an output DMP of the swallow counter 53. Needless to say, the swallow counter (pulse width variable swallow counter) illustrated in FIG. 12 is a mere example, and various ones may be adopted.

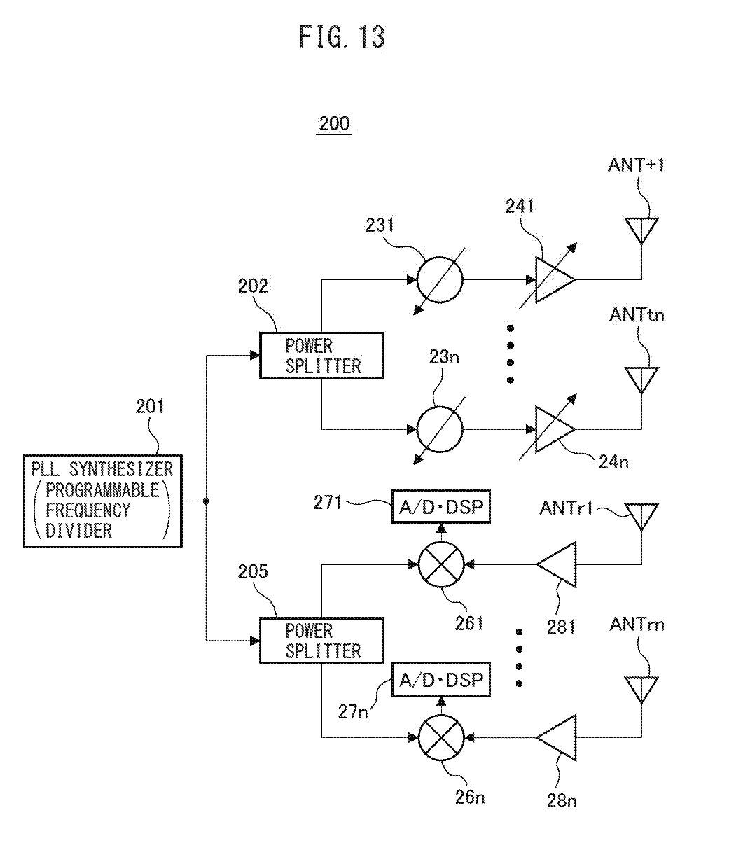

FIG. 13 is a block diagram illustrating an example of a radar device adopting the programmable frequency divider according to the present example. As illustrated in FIG. 13, a radar device 200 includes a PLL synthesizer 201 including the aforementioned programmable frequency divider 5 of the present example, and a power splitter 202 for transmission and a power splitter 205 for reception, both of which receive an output of the PLL synthesizer 201.

First, on the transmission side, outputs of the power splitter 202 are input to phase shifters 231, 232, . . . , 23n, and outputs of the phase shifters 231, 232, . . . , 23n are amplified by variable gain amplifiers (power amplifiers) 241, 242, . . . , 24n, and are output through transmission antennas ANTt1, ANTt2, . . ., ANTtn. The transmission antennas and the reception antennas are dedicated phased array antennas. However, needless to say, for example, a transmission and reception antenna with a duplexer may be used.

In addition, on the reception side, signals received via reception antennas ANTr1, ANTr2, . . . ANTrn are amplified by low-noise amplifiers 281, 282, . . . , 28n, and are mixed with outputs of the power splitter 205 with mixers 261, 262, . . . , 26n. Furthermore, outputs of the mixers 261, 262, . . . , 26n are processed with signal processing circuits 271, 272, . . . , 27n including an A/D converter and a DSP (Digital Signal Processor) and the like.

The aforementioned radar device 200 may be adopted, for example, as an FM-CW (Frequency Modulated Continuous Wave) radar that is mounted on an automobile to prevent collision or to carry out automatic driving while keeping a certain distance from a preceding vehicle. In addition, the programmable frequency divider 5 of the present example is not limited to be adopted to the aforementioned radar device 200, but may be adopted, for example, to radio communication equipment or various electronic devices that use a millimeter wave or the like.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A programmable frequency divider comprising:
a modulus frequency divider;
a pulse counter configured to count an output signal from the modulus frequency divider, and output a frequency division signal; and
a swallow counter configured to count the output signal from the modulus frequency divider and perform resetting on the basis of the frequency division signal from the pulse counter, the programmable frequency divider being configured to control the modulus frequency divider on the basis of a signal from the swallow counter, wherein
the programmable frequency divider includes a control signal delay circuit, disposed between an output terminal of the swallow counter and a control terminal of the modulus frequency divider, configured to delay a signal from the swallow counter, and generate a control signal for controlling the modulus frequency divider.

2. The programmable frequency divider according to claim 1, wherein the control signal delay circuit includes:
a plurality of delay lines with different delay amounts; and
a selector configured to select any one of the plurality of delay lines.

3. The programmable frequency divider according to claim 1, wherein
the swallow counter is a pulse width variable swallow counter configured to output a signal which is variable in pulse width.

4. The programmable frequency divider according to claim 3, wherein the pulse width variable swallow counter includes:
a plurality of flip-flops, connected in cascade, configured to fetch the reset signal on the basis of the output signal from the modulus frequency divider;
a plurality of variable delayers configured to variably delay, on the basis of delay control data, the output signal from the modulus frequency divider and an output of the plurality of flip-flops;
a plurality of logic gates configured to perform logical operation on an output of the plurality of variable delayers; and
a selector configured to select any of outputs of the plurality of logic gates.

5. The programmable frequency divider according to claim 1, wherein
the modulus frequency divider is a dual modulus frequency divider configured to switch between two frequency division ratios.

6. A PLL synthesizer comprising:
the programmable frequency divider according to claim 1;
a signal source configured to generate a first frequency signal;
a phase comparator configured to receive the first frequency signal and the frequency division signal from the programmable frequency divider, and perform phase comparison;
a low-pass filter configured to allow a low-frequency component of an output of the phase comparator to pass therethrough, and block a high-frequency component; and
an oscillator configured to generate and output a second frequency signal on the basis of an output of the low-pass filter, wherein
the second frequency signal is given to the programmable frequency divider as an input signal.

7. A radar device, wherein the PLL synthesizer according to claim 6 is mounted.

8. The radar device according to claim 7, the radar device further comprising:
a power splitter for transmission and a power splitter for reception, the power splitter for transmission and the power splitter for reception each receiving an output of the PLL synthesizer;
a plurality of phase shifters configured to receive and process a signal from the power splitter for transmission, and a plurality of variable gain amplifiers configured to amplify and output the processed signal from the power splitter for transmission via a transmission antenna;
a plurality of low-noise amplifiers configured to amplify a signal input from a reception antenna;
a plurality of mixers configured to mix an output of the plurality of low-noise amplifiers and an output of the power splitter for reception; and
a plurality of signal processing circuits configured to process an output of the plurality of mixers.

9. A programmable frequency divider comprising:
a modulus frequency divider;
a pulse counter configured to count an output signal from the modulus frequency divider, and output a frequency division signal; and
a swallow counter configured to count the output signal from the modulus frequency divider, and perform resetting on the basis of the frequency division signal from the pulse counter, the programmable frequency divider being configured to control the modulus frequency divider on the basis of an output from the swallow counter, wherein
the programmable frequency divider includes a reset signal delay circuit, disposed between an output terminal of the swallow counter and a reset terminal of the swallow counter, configured to delay the frequency division signal output from the swallow counter, and generate a reset signal for resetting the swallow counter.

10. The programmable frequency divider according to claim 9, the programmable frequency divider further comprising:
a control signal delay circuit, disposed between an output terminal of the swallow counter and a control terminal of the modulus frequency divider, configured to delay a signal from the swallow counter, and generate a control signal for controlling the modulus frequency divider.

11. The programmable frequency divider according to claim 9, wherein the control signal delay circuit includes:
a plurality of delay lines with different delay amounts; and
a selector configured to select any one of the plurality of delay lines.

12. The programmable frequency divider according to claim 9, wherein the reset signal delay circuit includes:
a plurality of delay lines configured to give different delay amounts; and
a selector configured to select any one of outputs of the plurality of delay lines.

13. The programmable frequency divider according to claim 9, wherein
the swallow counter is a pulse width variable swallow counter configured to output a signal which is variable in pulse width.

14. The programmable frequency divider according to claim 13, wherein the pulse width variable swallow counter includes:
a plurality of flip-flops, connected in cascade, configured to fetch the reset signal on the basis of the output signal from the modulus frequency divider;
a plurality of variable delayers configured to variably delay, on the basis of delay control data, the output signal from the modulus frequency divider and an output of the plurality of flip-flops;
a plurality of logic gates configured to perform logical operation on an output of the plurality of variable delayers; and
a selector configured to select any of outputs of the plurality of logic gates.

15. The programmable frequency divider according to claim 9, wherein
the modulus frequency divider is a dual modulus frequency divider configured to switch between two frequency division ratios.

16. A PLL synthesizer comprising:
the programmable frequency divider according to claim 9;
a signal source configured to generate a first frequency signal;
a phase comparator configured to receive the first frequency signal and the frequency division signal from the programmable frequency divider, and perform phase comparison;
a low-pass filter configured to allow a low-frequency component of an output of the phase comparator to pass therethrough, and block a high-frequency component; and
an oscillator configured to generate and output a second frequency signal on the basis of an output of the low-pass filter, wherein
the second frequency signal is given to the programmable frequency divider as an input signal.

17. A radar device, wherein the PLL synthesizer according to claim 16 is mounted.

18. The radar device according to claim 17, the radar device further comprising:
a power splitter for transmission and a power splitter for reception, the power splitter for transmission and the power splitter for reception each receiving an output of the PLL synthesizer;
a plurality of phase shifters configured to receive and process a signal from the power splitter for transmission, and a plurality of variable gain amplifiers configured to amplify and output the processed signal from the power splitter for transmission via a transmission antenna;
a plurality of low-noise amplifiers configured to amplify a signal input from a reception antenna;
a plurality of mixers configured to mix an output of the plurality of low-noise amplifiers and an output of the power splitter for reception; and
a plurality of signal processing circuits configured to process an output of the plurality of mixers.
